(19) United States
(12) Patent Application Publication
(10) Pub. No.: US 2018/0263136 A1
(43) Pub. Date: Sep. 13, 2018

(54) FLEXIBLE OR ROTATABLE CONNECTORS IN ELECTRONIC DEVICES

(71) Applicant: Microsoft Technology Licensing, LLC, Redmond, WA (US)

(72) Inventors: Rohit Koppal, Sammamish, WA (US); Chandra Subba, Redmond, WA (US)

(21) Appl. No.: 15/456,490

(22) Filed: Mar. 11, 2017

(51) Int. Cl. H05K 7/14; H05K 5/00

(52) U.S. Cl. CPC H05K 7/1407; H05K 7/1427; H05K 5/0017

(57) ABSTRACT

Devices having flexible or rotatable connectors between two components of an electronic device are described herein. The device may include a support structure and a plurality of connectors affixed to a surface of the support structure. The connectors are configured to connect the support structure with a component of an electronic device. Additionally, when the surface of the support structure is non-planar, each connector is configured to bend or rotate to maintain the connected component within a same plane.

### BACKGROUND

Current design trends for electronic devices such as tablet computers, display devices, or mobile phones include designs having an increase in power, a decrease in size (e.g., height, length, and/or width), and an increase in speed. As the size of the electronic device is reduced, certain internal device components may be positioned closer together. This provides for challenges in manufacturing design.

### SUMMARY

Flexible or rotatable connectors between two components of an electronic device are described herein. In one or more embodiments, a device includes a support structure and a plurality of connectors affixed to a surface of the support structure, wherein the plurality of connectors is configured to connect the support structure with a component of an electronic device, and wherein, when the surface of the support structure is non-planar, each connector of the plurality of connectors is configured to bend or rotate to maintain the connected component within a same plane.

In another embodiment, an electronic device includes a support structure, a component, and a plurality of connectors connecting a surface of the support structure with a surface of the component. Each connector of the plurality of connectors includes a flexible section. Additionally, when the surface of the support structure is non-planar, each connector of the plurality of connectors is configured to bend at the flexible section to maintain the surface of the connected component within a same plane.

In another embodiment, an electronic device includes a display module, a backing layer, an internal component positioned between the display module and the backing layer, and a plurality of connectors connecting a surface of the backing layer with a surface of the internal component. Additionally, when the surface of the support structure is non-planar, each connector of the plurality of connectors is configured to bend or rotate to maintain the surface of the connected component within a same plane.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

### DESCRIPTION OF THE DRAWING FIGURES

For a more complete understanding of the disclosure, reference is made to the following detailed description and accompanying drawing figures, in which like reference numerals may be used to identify like elements in the figures.

FIG. 1A depicts an example of a support component or structure with two screw bosses extending from the support structure, and a component connected to the base via screws inserted into the screw bosses.

FIG. 1B depicts an example of the support structure in FIG. 1A that has been curved or bent.

FIG. 2A depicts an example of a support structure having two connectors, each connector having a flexible section.

FIG. 2B depicts an example of the support structure in FIG. 2A that has been curved or bent.

FIG. 2C depicts an additional view of a connector in FIG. 2A.

FIG. 3A depicts a side-view of an additional example of a support structure having a connector with a flexible section.

FIG. 3B depicts a top-down view of the example in FIG. 3A.

FIG. 4 depicts an additional example of a support structure having a connector configured to bend.

FIG. 5 depicts an example of a support structure having a rotatable connector.

FIG. 6A depicts a first side-view of an additional example of a support structure having a rotatable connector.

FIG. 6B depicts a second side-view of the example in FIG. 6A.

FIG. 7 depicts an example of an electronic device with two components connected via a plurality of connectors.

FIG. 8 is a block diagram of a computing environment in accordance with one example of an electronic device described herein.

While the disclosed devices and systems are representative of embodiments in various forms, specific embodiments are illustrated in the drawings (and are hereafter described), with the understanding that the disclosure is intended to be illustrative, and is not intended to limit the claim scope to the specific embodiments described and illustrated herein.

### DETAILED DESCRIPTION

Disclosed herein are flexible or rotatable connectors positioned between two components of a device. Such flexible or rotatable connectors have several potential end-uses or applications, including being used to connect two components within an electronic device. The flexible or rotatable connector may be incorporated into an electronic device such as a personal computer, server computer, tablet or other handheld computing device, laptop or mobile computer, communication device such as mobile phone, multiprocessor system, microprocessor-based system, set top box, programmable consumer electronic, network PC, minicomputer, mainframe computer, or audio or video media player. In certain examples, the flexible or rotatable connectors may be incorporated within a wearable electronic device, wherein the device may be worn on or attached to a person's body or clothing. The wearable device may be attached to a person's shirt or jacket; worn on a person's wrist, ankle, waist, or head; or worn over their eyes or ears. Such wearable devices may include a watch, heart-rate monitor, activity tracker, or head-mounted display.

Flexible or rotatable connectors may be used to connect two components or structures of an electronic device. The connectors may be used to reduce or eliminate undesired forces created by one component from being observed by the second connected component. For example, imperfections or distortions in a first component developed during manufacturing of the component or created during use of the electronic device may avoid being transferred to the second component by connecting the two components using flexible or rotatable connectors.

Such flexible or rotatable connectors are advantageous for several reasons. First, the flexible or rotatable connectors may allow for cost improvements in manufacturing of the electronic device components. For instance, the design tolerances for manufacture of a first component of an electronic device (e.g., the support component or structure) may be relaxed to allow for slight imperfections (e.g., bends or curves) in the surface of the support structure. In other words, the flexible or rotatable connectors may be configured to offset such design imperfections from affecting the attached second component.

Second, the flexible or rotatable connectors may allow for thinner components to be attached to the support structure. Because there is less concern for deformation of the component by the support structure and the connectors, a thinner component (e.g., with reduced rigidity, stiffness, or strength) may be used. In other words, the improved connectors may reduce the amount of force (e.g., tension or strain forces) acting upon the connected component by the support structure, and therefore, a thinner and/or less rigid component may be used to counteract the reduced forces from the support structure.

Third, any additional components attached or adjacent to the connected component may also be modified (e.g., to be thinner or have reduced strength/stiffness/rigidity) because of the reduced forces acting on the components via the support structure and connected component.

Fourth, due to a reduced height or thickness of one or more components within the electronic device, the overall height or thickness of a stack of components within the electronic device may be reduced. In other words, the flexible or rotatable connector arrangement may allow for an overall thinner or smaller electronic device (e.g., as measured in the z-direction).

Fifth, the flexible or rotatable connectors may allow for improved reliability of the connected components. In other words, the improved connectors may reduce potential damage to a connected printed circuit board, therein improving the reliability of the connected circuit board.

Various non-limiting examples of electronic devices and components of the electronic devices are described in greater detail below.

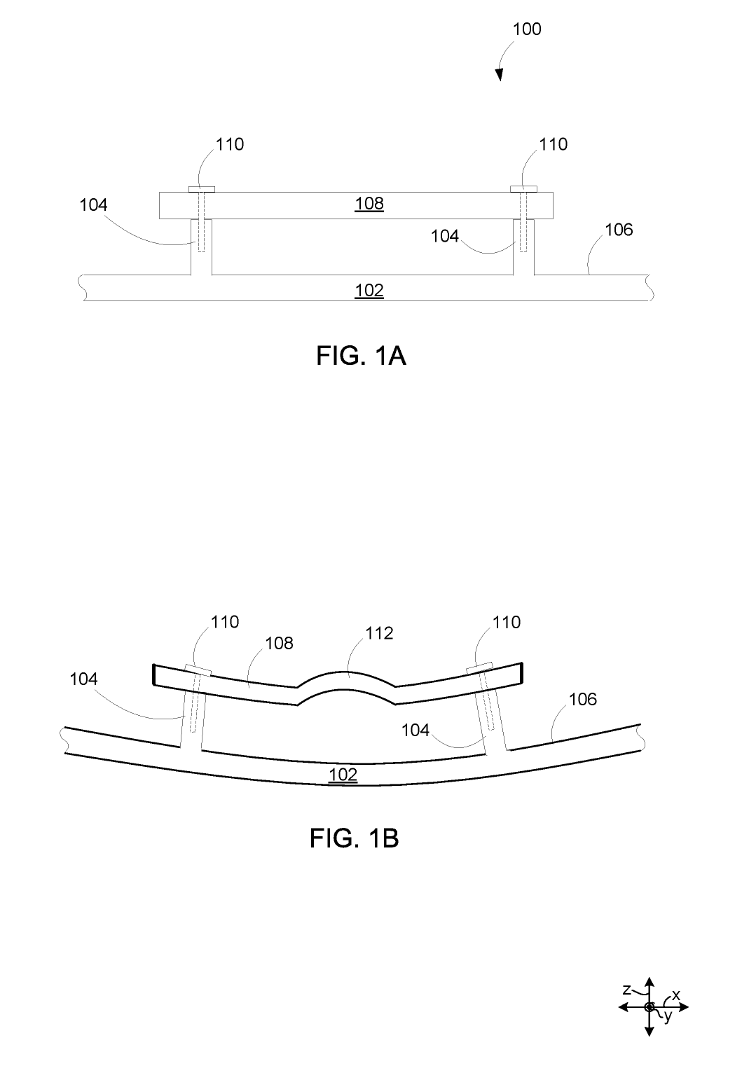

FIG. 1A depicts an example device 100 of a support structure 102 or component with two connectors 104 (e.g., screw bosses) extending perpendicularly from a surface 106 of the support structure 102. A component 108 (e.g., an electronic component) is connected to the support structure 102 via screws 110 inserted into the screw bosses 104. In this example, the screw boss connectors 104 are not flexible or rotatable (such that each connector 104 will extend perpendicularly from the surface of the support structure adjacent to the respective connector 104). The lack of flexibility or rotatability in the connectors 104 may be problematic if the surface 106 of the support structure 102 is not planar (e.g., curved, wavy, bumpy, or otherwise manufactured with some imperfection on the surface). The lack of flexibility or rotatability in the connectors 104 may also be problematic if the surface 106 of the support structure 102 becomes non-planar during subsequent assembly, shipment, or use of the electronic device. In some examples, a non-planar support structure may create a cosmetic or performance defect in the attached component.

FIG. 1B depicts an example of the potential cosmetic or performance defect in the component 108 when the surface 106 of the support structure 102 is non-planar. The support structure 102 has been bent or curved (e.g. during manufacturing or use of the device) such that the surface 108 of the support structure 102 no longer resides solely within the x, y-plane. Because the connectors 104 are non-flexible or non-rotatable, forces from the support structure 102 have been transferred to the attached component 108. The forces from the curved support structure 102 have overcome the stiffness or rigidity of the component 108, causing the component 108 to be pushed inward, creating a bulge or ridge 112 in the center of the component 108. This may be problematic in affecting the performance of the component 108 itself or any additional component connected to the component 108. Alternatively, or additionally, this bulge 112 or bending of the component 108 may create a visible cosmetic defect in the electronic device, therein lowering the perceived quality of manufacture of the device itself.

One solution to this problem is to connect the two components of the electronic device using flexible or rotatable connectors.

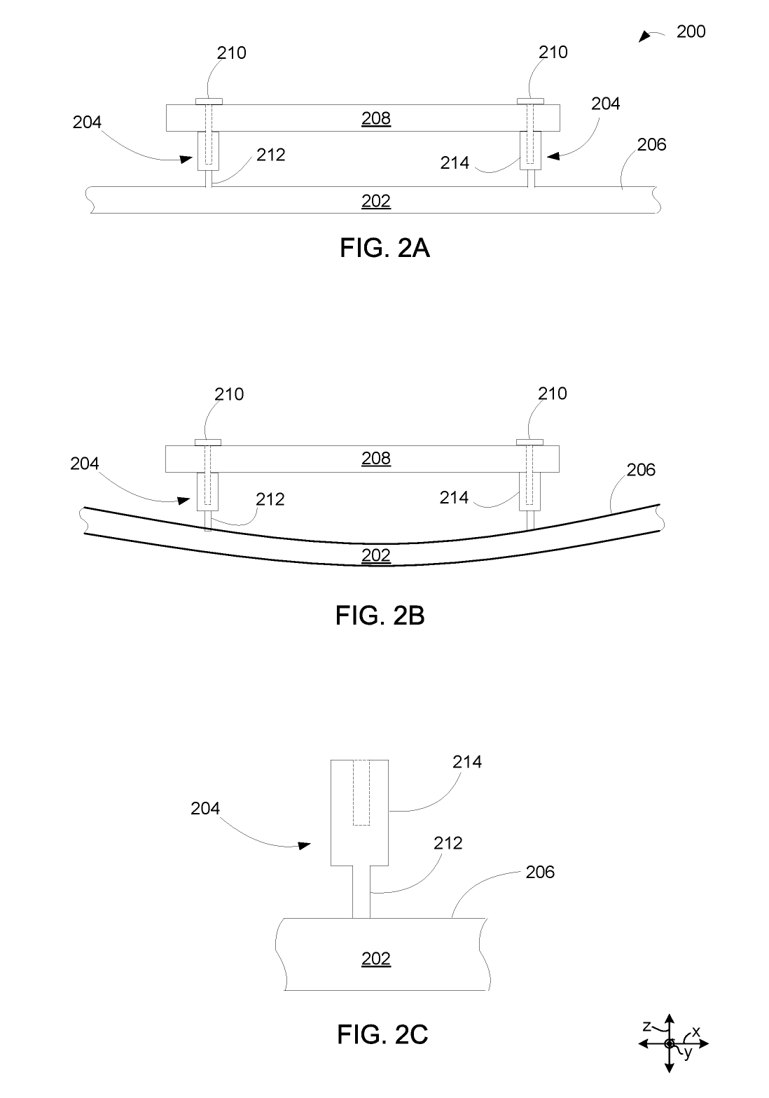

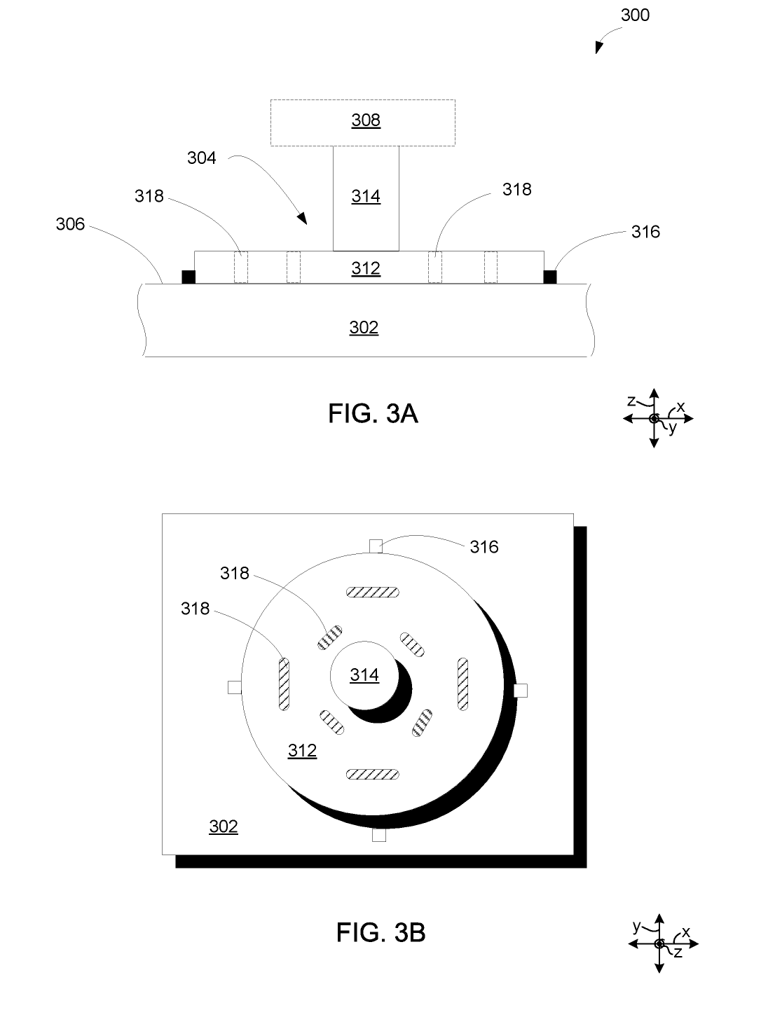

FIG. 2A depicts an example device 200 of a support structure 202 or structure having flexible connectors 204 extending from a surface 206 of the support structure 202. The flexible connectors 204 may be screw bosses, and a component 208 may be connected to the support structure 202 via screws 210 inserted into the screw bosses. Alternative mechanisms of connecting the component 208 to the support structure 202 are also possible. For example, the component may be connected to the support structure using a push button instead of a screw. Alternatively, the component may be soldered or adhered to the connectors. Additional examples are discussed below regarding FIGS. 3A-6B.

The connectors 204 are configured to bend, flex, or rotate to maintain the connected component 208 within a same plane (e.g., the x, y-plane). In other words, when the support structure 202 is bent or curved such that the surface 206 of the support structure 202 is non-planar, the connectors 204 are configured to bend or adjust such that the component 208 does not bend or otherwise deform as well (e.g., such that the component 208 remains within the x, y-plane).

For example, FIG. 2B depicts an example of the potential cosmetic or performance defect in the component 208 when the surface 206 of the support structure 202 is non-planar. The support structure 202 has been bent or curved (e.g. during manufacturing or use of the device) such that the surface 208 of the support structure 202 no longer resides solely within the x, y-plane. Because the connectors 204 are flexible, forces from the support structure 102 are dissipated by the connectors (e.g., by the bending of the connectors), therein protecting the attached component 208 from being deformed or damaged. In other words, the improved connectors 204 may reduce the amount of force (e.g., tension or strain forces) acting upon the connected component 208 by the support structure 202. This is advantageous, as noted above, because a thinner and/or less rigid component 208 may be used to counteract the reduced forces from the support structure.

The flexibility of the connectors may be achieved in several different ways, some of which are described herein.

For example, FIG. 2C depicts a larger view of a screw boss connector 204 depicted in FIGS. 2A and 2B. The screw boss connector 204 includes a flexible section 212 and a rigid section 214. The flexible section 212 may be positioned adjacent to the support structure 202 and the rigid section 214 may be positioned adjacent to the connectable component. In certain alternative examples, the flexible section is positionable adjacent to the component and the rigid section is positioned adjacent to the support structure.

The flexible section 212 is flexible or bendable because the stiffness of the flexible section 212 is less than the stiffness of the rigid section 214. A force applied to the connector 204 by the support structure 202 (e.g., based on a curved or non-planar support structure 202) will be observed at the flexible section 212 (e.g., the flexible section 212 will bend or otherwise deform).

The connector 204 may be configured to have a weaker, flexible section 212 based on the composition and/or the dimensions (e.g., diameter, width, circumference, or perimeter) of the flexible section, when compared with the composition and/or the dimensions of an adjacent rigid section 214.

In the example in FIG. 2C, the flexible section 212 and the rigid section 214 are made of a same composition. The flexible section 212 has a diameter or width 216 (e.g., as measured along the x-axis) that is smaller than a diameter or width 218 of the rigid section 214, thus providing a reduced stiffness of the flexible section 212 as compared with the rigid section 214.

Alternatively, the flexible and rigid sections may include two separate compositions or materials, wherein the flexible section is composed of a composition that is not as strong and/or stiff as the composition of the rigid section. In such an example, the flexible and rigid sections may have a same or different dimensions (e.g., diameter, width, circumference, or perimeter), so long as the stiffness of the flexible section is less than the stiffness rigid section.

The compositions and/or dimensions of the flexible and rigid sections may be configured to provide a desired capability of bending at the flexible section under typical design conditions without fracturing. The composition(s) of the connector 204 may be formed using any suitable material and/or combination of materials, such as metals, plastics, polymers, or alloys. In some examples, the flexible section and/or the rigid section of the connector 204 includes a polymer composition. The polymer composition may be an elastomer or a thermoplastic polymer. These polymer compositions may be advantageous for having the ability to resist a deforming force from the support structure and return to its original size and shape when the deforming force is removed. Examples of elastomers include unsaturated rubbers (e.g., polyisoprene, polybutadiene, chloroprene rubber, butyl rubber, styrene-butadiene, or nitrile rubber), saturated rubbers (e.g., ethylene propylene rubber, epichlorohydrin rubber, polyacrylic rubber, silicone rubber, fluorosilicone rubber, fluoroelastomers, perfluoroelastomers, polyether block amides, chlorosulfonated polyethylene, ethylene-vinyl acetate), thermoplastic elastomers, polysulfide rubber, or elastolefin. Thermoplastic polymers include acrylics such as polymethyl methacrylate (PMMA), acrylonitrile butadiene styrene (ABS), polyamides such as nylon, aliphatic polyesters such as polyactic acid (PLA), polybenzimidazole, polycarbonates, polyether sulfone (PES), polyether ether ketone (PEEK), polyetherimide (PEI), polyethylene (PE), polyphenylene oxide (PPO), polypheylene sulfide (PPS), polypropylene, polystyrene, polyvinyl chloride, or fluoropolymers such as polytetrafluoroethylene (PTFE).

In some examples, the composition of the flexible section 212 of the connector 204 is a material having a Young's modulus (i.e., a measure of stiffness) of 0.001-10 GigaPascal (GPa), 0.01-5 GPa, 0.1-1 GPa, less than 5 GPa, less than 1 GPa, or less than 0.1 GPa.

The dimensions of the connectors 204 (e.g., the flexible section 212 and rigid section 214 of the connectors 204) may be configured, in part, based on the type of material of the connectors 204. As noted above, the flexible section 212 is configured to bend to adjust for an uneven surface 206 in the support structure 202 (e.g., during manufacture or during use). Additionally, the flexible section 212 is configured to retain enough strength to avoid fracturing during the bending or flexing of the connector.

In certain examples, the diameter or width of the flexible section 212 of the connector 204 is 0.1-2 mm, 0.5-1 mm, 0.6-0.8 mm, less than 2 mm, less than 1 mm, or less than 0.5 mm. In certain examples, the circumference or perimeter of the flexible section 212 of the connector 204 is 0.1-10 mm, 1-5 mm, 2-3 mm, less than 10 mm, less than 5 mm, or less than 3 mm.

The height or thickness of the connector 204, as measured in the z-direction, is also variable. The height or thickness may be configured to be as small as possible while still providing support to secure the component 208 in place. The height may also be determined based upon the amount of available internal space within the electronic device such that the chosen height does not add any thickness to the overall device. In some examples, the height of the connector 204 is in a range from 0.01-10 mm, 0.1-5 mm, 0.1-1 mm, less than 10 mm, less than 5 mm, or less than 1 mm.

The shape of the connector 204 is also configurable. The flexible section 212 and the rigid section 214 may have a similar or different geometric shape. In some examples, the flexible and rigid sections may be cylinders or cuboids (e.g., cubes or rectangular prisms).

In some examples, the flexible connectors 204 and the support structure 202 are a single composition or piece of material. The flexible connectors 204 and the support structure 202 may be manufactured together. Alternatively, the flexible connectors 204 are manufactured separately from the support structure 202 and may be affixed to the surface 206 of the support structure 202 (e.g., via an adhesive, soldering, pressure, heat, or any other method of attaching two materials).

The number of connectors 204 may be configurable based on certain dimensions (e.g., length, width, perimeter) or other factors (e.g., weight, rigidity) of the component 208 connected to the support structure 202. In other words, a smaller, more rigid, and/or lighter weight component may require less connectors 204 than a larger, less rigid, and/or heavier component. The connectors 204 may be uniformly spaced apart from one another, or the connectors 204 may be positioned on the surface of the support structure based upon a preferred or available location to connect with the component 208. In certain examples, the distance between any two adjacent connectors is 10-100 mm, 10-50 mm, 30-50 mm, at least 10 mm, at least 30 mm, or at least 50 mm.

The type of components being connected within the electronic device is also configurable. The support structure and the component may both be internal components of the device. Alternatively, the support structure may be an external component and the component may be an internal component of the electronic device. In another example, the support structure may be an internal component and the component may be an external component of the electronic device.

In certain examples, the support structure 202 may be a chassis, bucket, or backing layer of the electronic device. In other examples, the support structure may be an internal component such as a touch sensor unit; a heat dissipation device such as a vapor chamber, heat pipe, heat sink, or heat fin; a battery; a processor; an integrated circuit; or printed circuit board.

In some examples, the component 208 is an electronic component. The electronic component may be an integrated circuit or printed circuit board. In some examples, the electronic component is a heat dissipation device such as a vapor chamber, heat pipe, heat sink, or heat fin. In other examples, the electronic component is a battery, touch sensor unit, or processor. In yet other examples, the component 208 is an external cover layer of the electronic device.

In addition to the examples depicted and discussed above in FIGS. 2A-2C, other types of connectors for connecting the component to the support structure are also possible. Some examples of alternative connectors are depicted and described below regarding FIGS. 3A-6B.

FIG. 3A depicts a side-view of an additional example device 300 of a support structure 302 and a connector 304 of a plurality of connectors. The connector 304 includes a plate 312 (e.g., a flexible section) and an extension 314 (e.g., a rigid section). The plate 312 is attached to a surface 306 of the support structure 302. The plate 312 may be attached to the surface 306 by adhering, soldering, pressure, heat, or any other method of attaching two materials). Alternatively, the plate 312 and the support structure 302 may be a single piece of material. In this example 300, the plate 312 is soldered to the surface at one or more solder joints 316.

The extension 314 is affixed to the plate 312 and is configured to be connected to the component 308. The extension 314 may be attached to the plate 312 and/or the component 308 by adhering, soldering, pressure, heat, or any other method of attaching two materials. In one example, the extension is a screw boss and is configured to be attached to the component via a screw. In some examples, the plate 312 and the extension 314 are a single piece of material.

As depicted in FIG. 3A, the plate 312 includes one or more cutouts 318, gaps, or openings within the section. The cutouts 318 are configured to weaken the strength of the plate 312, allowing the material to bend more easily at the plate 312. This allows the connector 304 to maintain connected to the component 208 within a same plane (e.g., the x, y-plane). In other words, when the support structure 302 is bent or curved such that the surface 306 of the support structure 302 is non-planar, the connector 304 is configured to bend or adjust at the plate 312 such that the component 308 does not bend or otherwise deform as well (e.g., such that the component 308 remains within the x, y-plane).

The size, shape, location, and number of cutouts 318 is configurable based on the desired strength and flexibility of the plate 312. In certain examples, the cutouts 318 extend through the entire depth (as measured in the z-direction) of the plate 312. In other examples, the cutouts do not extent entirely through the plate 312. In certain examples, the size, shape, location, and number of cutouts 318 is configured to allow bending or flexibility in the x- and y-directions, but restrict movement in the z-direction.

The compositions and/or dimensions of the plate and extension may be configured to provide a desired capability of bending at the plate 312 (e.g., flexible section) under typical design conditions without fracturing. The composition(s) of the plate and extension may be formed using any suitable material and/or combination of materials, such as metals, plastics, polymers, or alloys. Examples of such components are discussed above regarding FIGS. 2A-2C.

In certain examples, the plate 312 is a metal plate. The metal plate may have a composition including aluminum, copper, lead, zinc, tin, titanium, magnesium, nickel, tin, carbon, or an alloy thereof. In some examples, the metal plate composition is an alloy such as steel (e.g., stainless steel).

The height or thickness of the plate 312 (as viewed in the z-direction) is configurable. In certain examples, the height is 0.01-5 mm, 0.1-1 mm, 0.2-0.5 mm, less than 1 mm, less than 0.5 mm, less than 0.2 mm, or less than 0.1 mm.

FIG. 3B depicts a top-down view of the example 300 in FIG. 3A. The plate 312 includes a plurality of cutouts 318 surrounding the extension 314 of the connector 304. Positioning of the cutouts 318 around the extension 314 is advantageous in allowing the connector 304 to bend in any direction.

The plate 312 and extension 314 are depicted in FIG. 3B as cylindrical structures. Alternative shapes of the connector sections are also possible. In some examples, the shape of the plate and/or extension may be a cuboid (e.g., a cube or rectangular prism).

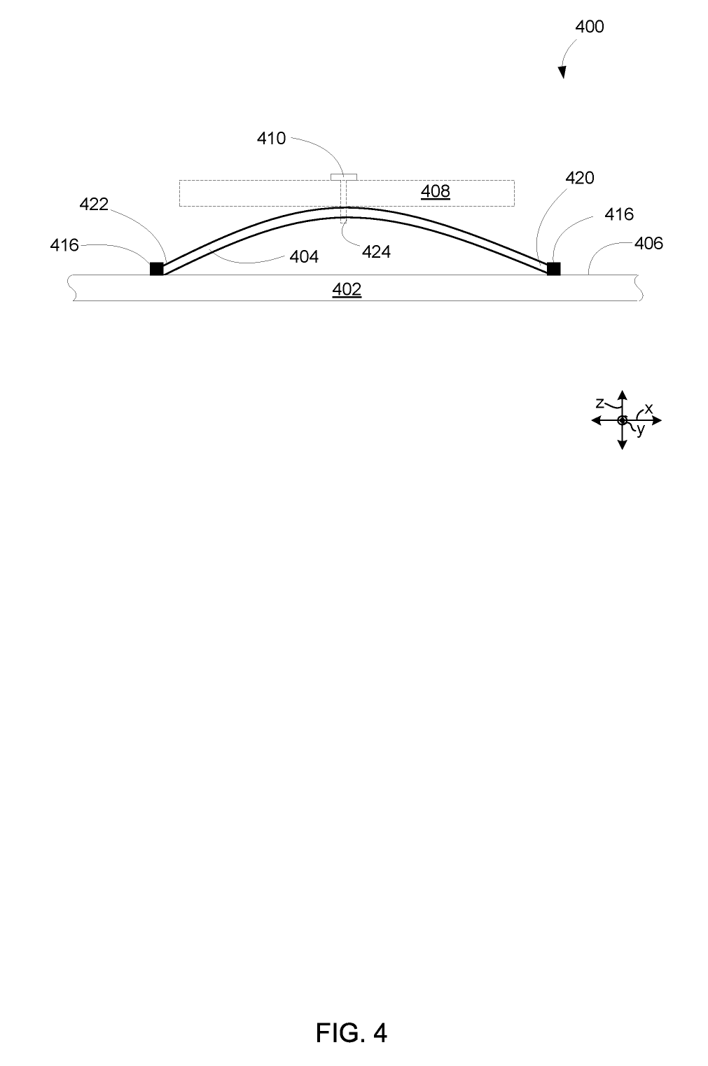

FIG. 4 depicts an additional example device 400 of a support structure 402 having a connector 404 configured to bend. The connector 404 is an arch having two arch bases 420, 422 and an apex 424 positioned between the arch bases 420, 422. In an alternative example, the connector 404 is a partial dome having a dome base and an apex.

The connector 404 is affixed to the support structure 402 and is configured to be connected to the component 408. The connector 404 may be attached to the support structure 402 and/or the component 408 by adhering, soldering, pressure, heat, or any other method of attaching two materials. As depicted in FIG. 4, the connector 404 is affixed to the support structure 402 at the two arch bases 420, 422 at soldering joints 416. Additionally, the connector 404 is attached to the component 408 at the apex of the arch via a screw or push button 410.

The arch or partial dome is configured to bend or flex to maintain the connected component 408 within a same plane (e.g., the x, y-plane). In other words, when the support structure 402 is bent or curved such that the surface 406 of the support structure 402 is non-planar, the arch or dome is configured to bend or adjust such that the component 408 does not bend or otherwise deform as well (e.g., such that the component 408 remains within the x, y-plane).

The compositions and/or dimensions (e.g., height, width, length, thickness) of the arch or partial dome may be configured to provide a desired capability of bending under typical design conditions without fracturing. The composition(s) of the arch or dome may be formed using any suitable material and/or combination of materials, such as the metals, plastics, polymers, or alloys discussed above.

In certain examples, the shape of the arch is a triangular arch, round or semi-circular arch, segmental arch, lancet arch, equilateral pointed arch, shouldered flat arch, horseshoe arch, three-centered arch, elliptical arch, inflexed arch, ogee arch, reverse ogee arch, tudor arch, or parabolic arch. In other examples, the shape of the partial dome is in a shape of a beehive dome, braced dome, cloister vault, crossed-arch dome, geodesic dome, hemispherical dome, onion dome, oval dome, parabolic dome, sail dome, saucer dome, or umbrella dome.

The thickness of the material of the arch or partial dome (as measured in the z-direction) may be 0.1-2 mm, 0.5-1 mm, 0.6-0.8 mm, less than 2 mm, less than 1 mm, or less than 0.5 mm. In certain examples, the height (e.g., as measured between the surface of 406 of the support structure 402 and the component 408) and/or the width or length (e.g., as measured between the solder joints) of the arch or partial dome is 1-10 mm, 1-5 mm, 2-3 mm, less than 10 mm, less than 5 mm, or less than 3 mm.

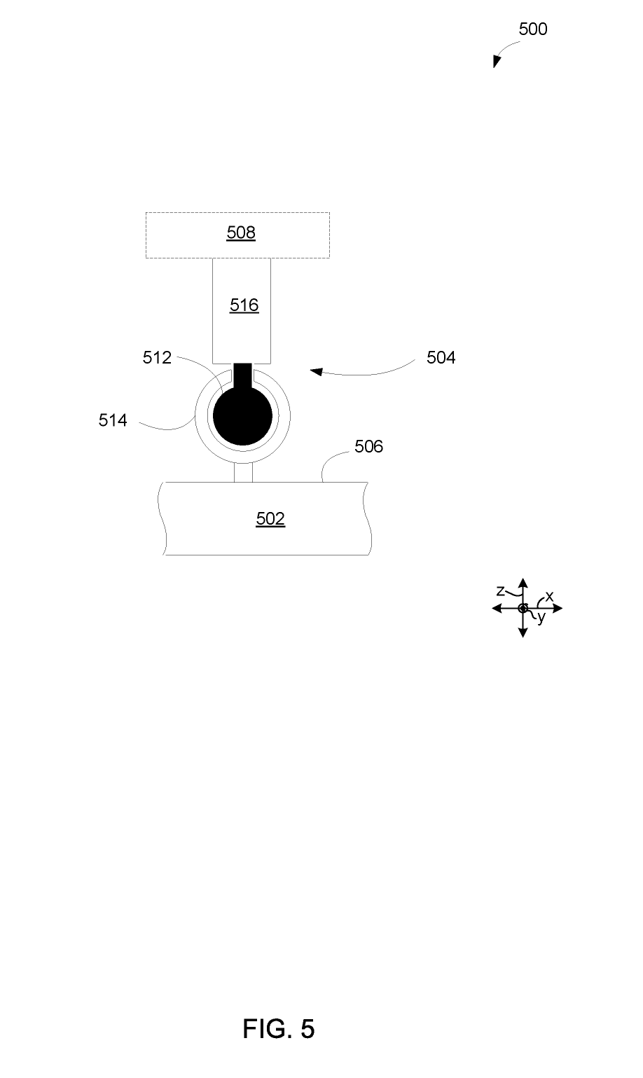

FIG. 5 depicts an additional example device 500 of a support structure 502 having a connector 504 configured to rotate about at least one axis. The connector 504 includes a ball 512 and socket 514. The socket 514 is attached to the surface 506 of the support structure 502 by adhering, soldering, pressure, heat, or any other method of attaching the two materials. Alternatively, the socket 514 and the support structure 502 are a single piece of material.

The ball 512 is attached to an extension 516 configured to be connected to the component 508. The ball 512 and extension 516 may be a single piece of material. Alternatively, the ball 512 and extension 516 may be affixed to each other via adhering, soldering, pressure, heat, or any other method of attaching the two materials. Additionally, the extension 516 and the component 508 may also be affixed to each other via adhering, soldering, pressure, heat, or any other method of attaching the two materials.

The connector 504 including the ball 512 and socket 514 is configured to rotate about one or more axes to maintain the connected component 508 within a same plane (e.g., the x, y-plane). In other words, when the support structure 502 is bent or curved such that the surface 506 of the support structure 502 is non-planar, the ball 512 is configured to rotate within the socket 514 such that the component 508 does not bend or otherwise deform as well (e.g., such that the component 508 remains within the x, y-plane).

The compositions and/or dimensions (e.g., external diameter of the ball, internal diameter of the socket, external diameter of the socket) of the connector components may be configured to provide a desired rotation capability. The composition(s) of the ball, socket, and extension may be formed using any suitable material and/or combination of materials, such as the metals, plastics, polymers, or alloys discussed above.

In certain examples, the external diameter of the ball may be 0.1-5 mm, 0.5-1 mm, 0.1-0.5 mm, less than 5 mm, less than 1 mm, or less than 0.5 mm. In certain examples, the gap or average distance between the surface of the ball and the internal surface of the socket may be 0.01-1 mm, 0.01-0.5 mm, 0.01-0.1 mm, less than 1 mm, less than 0.5 mm, less than 0.1 mm, or less than 0.01 mm. In some examples, the surface of the ball and the internal surface of the socket have a friction fit (e.g., no gap).

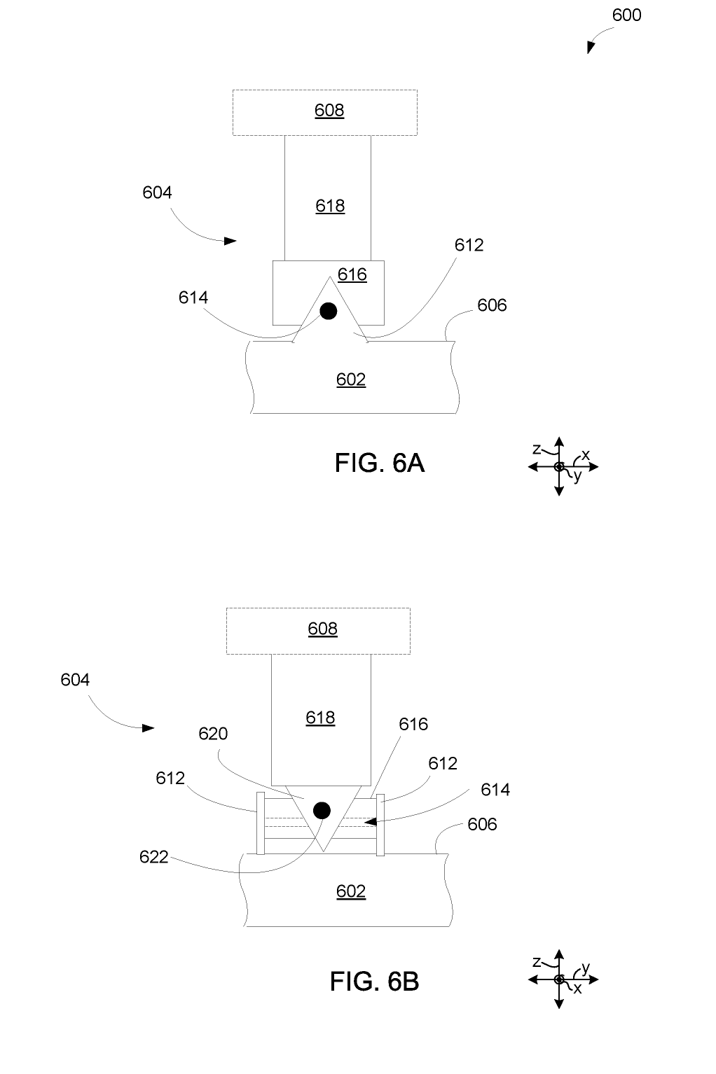

FIG. 6A depicts a first side-view of an additional example device 600 of a support structure having a rotatable connector. The device 600 includes support structure 602 having a connector 604 configured to rotate about at least one axis. The connector 604 includes a first pin housing 612, a first cylindrical pin 614, a lower extension 616, and an upper extension 618.

The first pin housing 612 may be affixed to a surface 606 of the support structure 602 by adhering, soldering, pressure, heat, or any other method of attaching the two materials. Alternatively, the first pin housing 612 and the support structure 602 may be a single piece of material.

The first pin housing 612 may include two pin housings positioned on either end of the lower extension 616, configured to bookend the lower extension 616 of the connector 604.

The first cylindrical pin 614 extends through the first pin housing 612 and lower extension 616 along the y-axis, therein allowing the connector 604 to rotate about the y-axis.

The lower extension 616 is affixed to the upper extension 618, which in turn is configured to be affixed to the component 608. These connections may be made by adhering, soldering, pressure, heat, or any other method of attaching the two materials. Alternatively, the lower extension 616 and the upper extension 618 may be a single piece of material.

FIG. 6B depicts a second side-view of the example in FIG. 6A. In this example device, the connector 604 includes a second pin housing 620 and a second cylindrical pin 622. The second pin housing 620 may be affixed to the upper extension 618 of the connector via adhering, soldering, pressure, heat, or any other method. Alternatively, the second pin housing 620 and the upper extension 618 may be a single piece of material.

The second pin housing 620 may include two pin housings positioned on either end of the lower extension 616, configured to bookend the lower extension 616 of the connector 604.

The second cylindrical pin 622 extends through the second pin housing 620 and lower extension 616 along the x-axis, therein allowing the connector 604 to rotate about the x-axis.

In other words, when the support structure 602 is bent or curved such that the surface 606 of the support structure 602 is non-planar, the connector 604 configured to rotate about the first and/or second cylindrical pin 614, 622 such that the component 608 does not bend or otherwise deform as well (e.g., such that the component 608 remains within the x, y-plane).

The compositions and/or dimensions of the connector components may be configured to provide a desired rotation capability. The composition(s) of the first pin housing 612, first cylindrical pin 614, lower extension 616, upper extension 618, second pin housing 620, and second cylindrical pin 622 may be formed using any suitable material and/or combination of materials, such as the metals, plastics, polymers, or alloys discussed above.

In certain examples, the external diameter of the first or second cylindrical pin may be 0.1-5 mm, 0.5-1 mm, 0.1-0.5 mm, less than 5 mm, less than 1 mm, or less than 0.5 mm. In certain examples, the length of the first or second cylindrical pin (as measured along the pin's axis of rotation) may be 0.1-10 mm, 1-5 mm, 2-3 mm, less than 10 mm, less than 5 mm, or less than 3 mm.

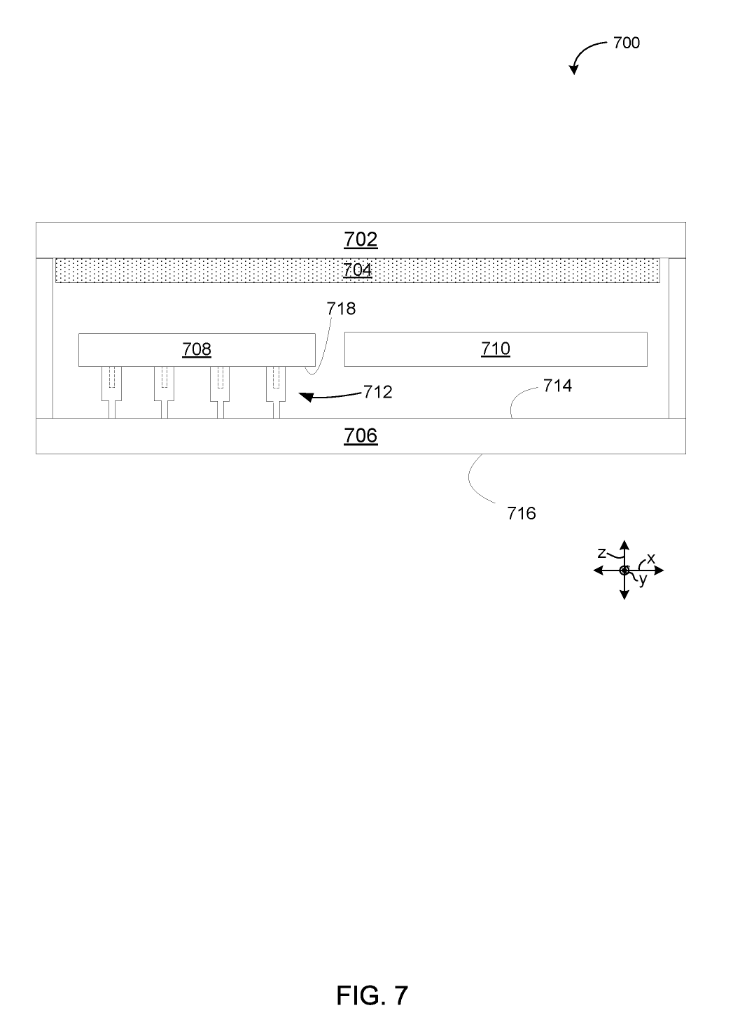

FIG. 7 depicts a non-limiting example of an electronic device 700 having two components of the device 700 connected via a plurality of connectors. The electronic device 700 includes a display screen or display module 702. The display module 702 may be a touch display module. The display module 702 may include a light-emitting device such as a liquid crystal display (LCD) or a light emitting diode (LED) (e.g., an organic light emitting diode (OLED)). The LCD or LED may be disposed in, or configured as, a film. The configuration, construction, materials, and other aspects of the light emitting devices may vary. For instance, III-V semiconductor-based LED structures may be used to fabricate micron-sized LED devices. The small thickness of such structures allows the light emitting devices to be disposed in planar arrangements (e.g., on or in planar surfaces) and thus, distributed across the viewable area of the display. Non-LED technologies, such as finely tuned quantum dot-based emission structures, may also be used. Other thin form factor emission technologies, whether developed, in development, or future developed, may be used within the display module 702.

In certain examples, the display module includes a back plate 704. The back plate 704 may be bonded (e.g., adhesively bonded) to the LCD or LED.

The electronic device 700 further includes a backing layer 706, bucket, or chassis. The backing layer 706 is positioned on the rear end of the electronic device 700 such that the display module 702 and backing layer 706 bookend the internal components of the electronic device 700. The backing layer 706 may be made of any variety of materials now known or later developed such as metals, plastics, polymers, ceramics, or combinations thereof, including the materials described above. For instance, the backing layer 706 may be formed from one or more sub-layers of a polymer or mixture of polymers. For example, the backing layer 706 may be formed from polymers such as thermoplastic polymers, silicones, or polyurethanes.

Positioned between the back plate 704 of the display module 702 and the backing layer 706 are the internal components of the electronic device 700. One internal component is a circuit board or motherboard 708. The circuit board 708 may be a printed circuit board or a flexible circuit board. The circuit board 708 may be configured to hold and allow communication between one or more central processing units (CPUs), graphics processing units (GPUs), and memories. The circuit board 708 may also be configured to provide connections to sound cards, video cards, network cards, hard drives, or other forms of storage. The circuit board 708 may also be configured to provide connections to one or more peripherals (e.g., a keyboard, mouse, serial port, parallel port, Firewire/IEEE 1394a, universal serial bus (USB), Ethernet, audio).

Another internal component within the electronic device 700 is the battery 710. In certain examples, the electronic device may include a plurality (i.e., 2 or more) of batteries. The battery 710 may be any type of battery now known or later developed. In certain examples, the battery is a secondary or rechargeable battery (e.g., a metal ion or metal air battery such as a lithium air or lithium ion battery). In some examples, the battery may be in the same plane as the motherboard (e.g., the same x-y plane, as depicted in FIG. 7). In other examples, the battery may be in a different plane from the motherboard, wherein the battery plane is parallel with the motherboard plane (e.g., the x-y plane of the battery is at a different z height from the x-y plane of the motherboard).

The electronic device 700 may include additional internal components between the display module 702 and the backing layer 706. For example, the electronic device 700 may include an active cooling source (e.g., a fan). As used herein, “active cooling” may refer to the use of forced fluid movement (e.g. fans moving air or pumps moving water) to reduce the heat of a component (e.g., a microprocessor) of the electronic device. Active cooling contrasts with “passive cooling,” which utilizes non-forced methods of cooling such as natural convection or radiation or involves reducing the speed at which a component (e.g., a microprocessor) is running to reduce the component's heat. The fan, when active, may drive air through areas or channels within the internal area of the electronic device to assist in removing heat from the electronic device.

Any two components of the electronic device 700 may be connected to each other via a plurality of connectors. Non-limiting examples of the plurality of connectors are described above regarding FIGS. 2A-6B.

In the example depicted in FIG. 7, a plurality of connectors 712 are positioned on an internal surface 714 of the backing layer 706. The plurality of connectors 712 connect a surface 718 of the circuit board 708 with a surface 714 of the backing layer 706. In an alternative example, the plurality of connectors 712 may be used to connect two internal components to each other. In another example, the plurality of connectors 712 may be used to connect the backing layer 706 with a different internal component or plurality of internal components (e.g., a heat dissipation device). In yet another example, the plurality of connectors 712 may be positioned on an outer surface 716 of the backing layer 706 and used to connect the backing layer with a different component of the electronic device (e.g., a cover layer).

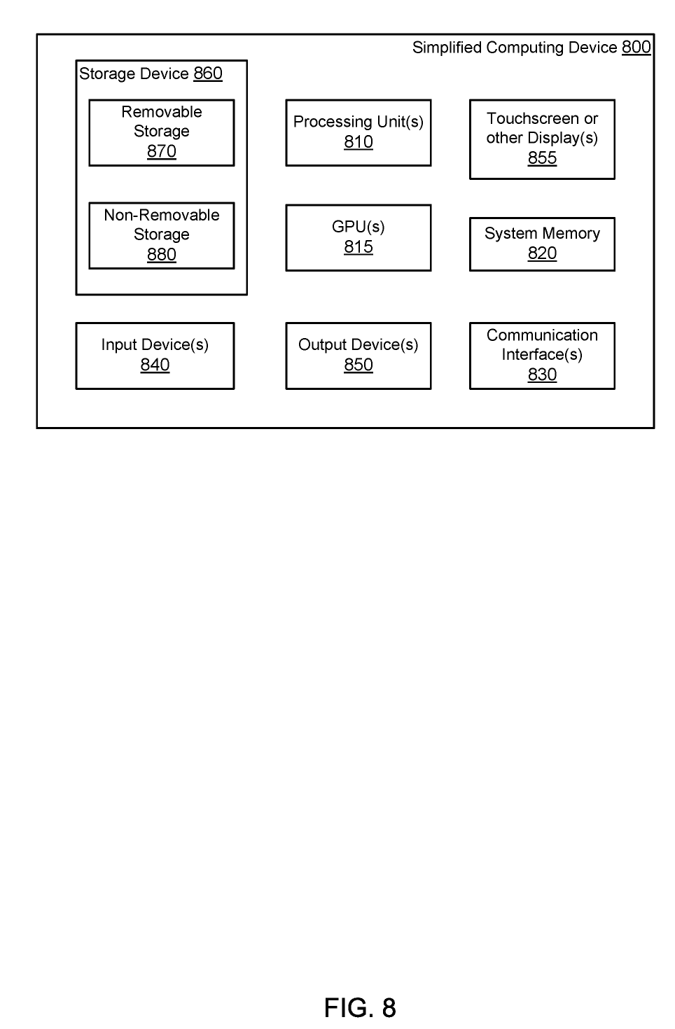

Regarding FIG. 8, the devices described above may be incorporated within an exemplary computing environment 800. The computing environment 800 may correspond with one of a wide variety of computing devices, including, but not limited to, personal computers (PCs), server computers, tablet and other handheld computing devices, laptop or mobile computers, communications devices such as mobile phones, multiprocessor systems, microprocessor-based systems, set top boxes, programmable consumer electronics, network PCs, minicomputers, mainframe computers, or audio or video media players. In certain examples, the computing device may be a wearable electronic device, wherein the device may be worn on or attached to a person's body or clothing. The wearable device may be attached to a person's shirt or jacket; worn on a person's wrist, ankle, waist, or head; or worn over their eyes or ears. Such wearable devices may include a watch, heart-rate monitor, activity tracker, or head-mounted display.

The computing environment 800 has sufficient computational capability and system memory to enable basic computational operations. In this example, the computing environment 800 includes one or more processing unit(s) 810, which may be individually or collectively referred to herein as a processor. The computing environment 800 may also include one or more graphics processing units (GPUs) 815. The processor 810 and/or the GPU 815 may include integrated memory and/or be in communication with system memory 820. The processor 810 and/or the GPU 815 may be a specialized microprocessor, such as a digital signal processor (DSP), a very long instruction word (VLIW) processor, or other microcontroller, or may be a general-purpose central processing unit (CPU) having one or more processing cores. The processor 810, the GPU 815, the system memory 820, and/or any other components of the computing environment 800 may be packaged or otherwise integrated as a system on a chip (SoC), application-specific integrated circuit (ASIC), or other integrated circuit or system.

The computing environment 800 may also include other components, such as, for example, a communications interface 830. One or more computer input devices 840 (e.g., pointing devices, keyboards, audio input devices, video input devices, haptic input devices, or devices for receiving wired or wireless data transmissions) may be provided. The input devices 840 may include one or more touch-sensitive surfaces, such as track pads. Various output devices 850, including touchscreen or touch-sensitive display(s) 855, may also be provided. The output devices 850 may include a variety of different audio output devices, video output devices, and/or devices for transmitting wired or wireless data transmissions.

The computing environment 800 may also include a variety of computer readable media for storage of information such as computer-readable or computer-executable instructions, data structures, program modules, or other data. Computer readable media may be any available media accessible via storage devices 860 and includes both volatile and nonvolatile media, whether in removable storage 870 and/or non-removable storage 880. Computer readable media may include computer storage media and communication media. Computer storage media may include volatile and nonvolatile, removable and non-removable media implemented in any method or technology for storage of information such as computer readable instructions, data structures, program modules or other data. Computer storage media includes, but is not limited to, RAM, ROM, EEPROM, flash memory or other memory technology, CD-ROM, digital versatile disks (DVD) or other optical disk storage, magnetic cassettes, magnetic tape, magnetic disk storage or other magnetic storage devices, or any other medium which may be used to store the desired information and which may be accessed by the processing units of the computing environment 800.

While the present claim scope has been described with reference to specific examples, which are intended to be illustrative only and not to be limiting of the claim scope, it will be apparent to those of ordinary skill in the art that changes, additions and/or deletions may be made to the disclosed embodiments without departing from the spirit and scope of the claims.

The foregoing description is given for clearness of understanding only, and no unnecessary limitations should be understood therefrom, as modifications within the scope of the claims may be apparent to those having ordinary skill in the art.

### Claim Support Section

In a first embodiment, a device comprises a support structure; and a plurality of connectors affixed to a surface of the support structure, wherein the plurality of connectors is configured to connect the support structure with a component of an electronic device, and wherein, when the surface of the support structure is non-planar, each connector of the plurality of connectors is configured to bend or rotate to maintain the connected component within a same plane.

In a second embodiment, an electronic device comprises a support structure; a component; and a plurality of connectors connecting a surface of the support structure with a surface of the component, wherein each connector of the plurality of connectors comprises a flexible section, and wherein, when the surface of the support structure is non-planar, each connector of the plurality of connectors is configured to bend at the flexible section to maintain the surface of the connected component within a same plane.

In a third embodiment, an electronic device comprises a display module; a backing layer; an internal component positioned between the display module and the backing layer; and a plurality of connectors connecting a surface of the backing layer with a surface of the internal component, wherein, when the surface of the backing layer is non-planar, each connector of the plurality of connectors is configured to bend or rotate to maintain the surface of the internal component within a same plane.

In a fourth embodiment, with reference to any of embodiments 1-3, each connector of the plurality of connectors is configured to rotate about at least one axis.

In a fifth embodiment, with reference to any of embodiments 1-4, each connector of the plurality of connectors comprises a flexible section, and wherein each connector of the plurality of connectors is configured to bend at the flexible section.

In a sixth embodiment, with reference to the fifth embodiment, each connector of the plurality of connectors further comprises a rigid section, wherein the flexible section is positioned adjacent to the support structure and the rigid section is positionable adjacent to the component of the electronic device, and wherein a diameter of the flexible section is less than a diameter of the rigid section.

In a seventh embodiment, with reference to the sixth embodiment, the plurality of connectors is a plurality of screw bosses.

In an eighth embodiment, with reference to any of embodiments 1-7, each connector of the plurality of connectors comprises a plate affixed to the surface of the support structure and an extension affixed to the plate, wherein the plate comprises cutouts positioned around the extension.

In a ninth embodiment, with reference to the eighth embodiment, the extension of each connector of the plurality of connectors is a screw boss.

In a tenth embodiment, with reference to any of embodiments 1-3, each connector of the plurality of connectors comprises a socket and a ball joint, wherein the socket is connected to the surface of the support structure and the ball joint is connectable with the component of the electronic device.

In an eleventh embodiment, with reference to any of embodiments 1-3, each connector of the plurality of connectors comprises at least one cylindrical pin positioned adjacent to the surface of the support structure, wherein each cylindrical pin provides an axis of rotation.

In a twelfth embodiment, with reference to any of embodiments 1-3, each connector of the plurality of connectors comprises an arch having two arch bases and an apex positioned between the arch bases, wherein each connector is affixed to the support structure at the two arch bases, and wherein each connector is configured to be attached to the component of the electronic device at the apex of the arch.

In a thirteenth embodiment, with reference to any of embodiments 1-3, each connector of the plurality of connectors comprises a partial dome having a base and an apex, wherein each connector is affixed to the support structure at the base of the partial dome, and wherein each connector is configured to be attached to the component of the electronic device at the apex of the partial dome.

In a fourteenth embodiment, with reference to any of embodiments 1-13, the support structure and the plurality of connectors are a single piece of material.

In a fifteenth embodiment, with reference to any of embodiments 1-14, the component or internal component is a printed circuit board.

In a sixteenth embodiment, with reference to any of embodiments 1-15, the support structure is a backing layer.

1. A device comprising:
a support structure; and
a plurality of connectors affixed to a surface of the support structure, each connector comprising a flexible section affixed to the surface of the support structure,
wherein the plurality of connectors is configured to connect the support structure with a component of an electronic device, and
wherein, when the surface of the support structure is non-planar, each connector of the plurality of connectors is configured to bend at the flexible section to maintain the connected component within a same plane.

2.-3. (canceled)

4. The device of claim 1, wherein each connector of the plurality of connectors further comprises a rigid section,
wherein the rigid section is positionable adjacent to the component of the electronic device, and
wherein a diameter of the flexible section is less than a diameter of the rigid section.

5. The device of claim 4, wherein the plurality of connectors is a plurality of screw bosses.

6. The device of claim 1, wherein each connector of the plurality of connectors comprises a plate affixed to the surface of the support structure and an extension affixed to the plate,
wherein the plate comprises cutouts positioned around the extension.

7. The device of claim 6, wherein the extension of each connector of the plurality of connectors is a screw boss.

8. The device of claim 1, wherein each connector of the plurality of connectors comprises a socket and a ball joint,
wherein the socket is connected to the surface of the support structure and the ball joint is connectable with the component of the electronic device.

9. The device of claim 1, wherein each connector of the plurality of connectors comprises at least one cylindrical pin positioned adjacent to the surface of the support structure,
wherein each cylindrical pin provides an axis of rotation.

10. The device of claim 1, wherein each connector of the plurality of connectors comprises an arch having two arch bases and an apex positioned between the arch bases,
wherein each connector is affixed to the support structure at the two arch bases, and
wherein each connector is configured to be attached to the component of the electronic device at the apex of the arch.

11. The device of claim 1, wherein each connector of the plurality of connectors comprises a partial dome having a base and an apex,
wherein each connector is affixed to the support structure at the base of the partial dome, and
wherein each connector is configured to be attached to the component of the electronic device at the apex of the partial dome.

12. The device of claim 1, wherein the support structure and the plurality of connectors are a single piece of material.

13. An electronic device comprising:
a support structure;
a component; and
a plurality of connectors connecting a surface of the support structure with a surface of the component,
wherein each connector of the plurality of connectors comprises a flexible section attached to or extending from the surface of the support structure, and
wherein, when the surface of the support structure is non-planar, each connector of the plurality of connectors is configured to bend at the flexible section to maintain the surface of the connected component within a same plane.

14. The electronic device of claim 13, wherein the component is a printed circuit board.

15. The electronic device of claim 13, wherein the support structure is a backing layer.

16. The electronic device of claim 13, wherein each connector of the plurality of connectors further comprises a rigid section,
wherein the rigid section is positionable adjacent to the component of the electronic device, and
wherein a diameter of the flexible section is less than a diameter of the rigid section.

17. The electronic device of claim 13, wherein each connector of the plurality of connectors comprises a plate affixed to the surface of the support structure and an extension affixed to the plate,
wherein the plate comprises cutouts positioned around the extension.

18. An electronic device comprising:
a display module;
a backing layer;
an internal component positioned between the display module and the backing layer; and
a plurality of connectors connecting a surface of the backing layer with a surface of the internal component,
wherein, when the surface of the backing layer is non-planar, each connector of the plurality of connectors is configured to bend or rotate to maintain the surface of the internal component within a same plane.

19. The electronic device of claim 18, wherein the internal component is a printed circuit board.

20. The electronic device of claim 18, wherein each connector of the plurality of connectors is a screw boss comprising a flexible section and a rigid section,
wherein each connector of the plurality of connectors is configured to bend at the flexible section,
wherein the flexible section is positioned adjacent to the backing layer and the rigid section is positioned adjacent to the internal component, and
wherein a diameter of the flexible section is less than a diameter of the rigid section.
